(19) United States
(12) Patent Application Publication
(10) Pub. No.: US 2006/0186425 A1
(43) Pub. Date: Aug. 24, 2006

(54) LED lamp

(75) Inventors: Tadashi Yano, Kyoto (JP); Masanori Shimizu, Kyoto (JP); Kiyoshi Takahashi, Kyoto (JP); Yoshihiko Kanayama, Hyogo (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd., Osaka (JP)

(21) Appl. No.: 11/402,928

(22) Filed: Apr. 13, 2006

Related U.S. Application Data
(63) Continuation-in-part of application No. PCT/JP05/00654, filed on Jan. 20, 2005.

(30) Foreign Application Priority Data
Jan. 29, 2004 (JP) 2004-021062

(51) Int. Cl. H01L 33/00

(52) U.S. Cl. 257/98

(57) ABSTRACT

An LED lamp 100 according to the present invention includes: a substrate 20 with an upper surface; a plurality of LED chips 10, which are arranged on the upper surface of the substrate 20; and a reflector 30, which has reflective surfaces that reflect emissions of the respective LED chips 10 at least partially. The reflector 30 includes a resin and a framework that is made of a material having a higher flexural rigidity than the resin.

This is a continuation of International Application PCT/JP2005/000654, with an international filing date of Jan. 20, 2005, which claims priority of Japanese Patent Application No. 2004-021062, filed on Jan. 29, 2004, the contents of which are hereby incorporated by reference.

### BACKGROUND OF THE INVENTION

1. Field of the Invention

The present invention relates to an LED lamp and more particularly relates to an LED lamp that can be used effectively as a white light source for general illumination.

2. Description of the Related Art

A light emitting diode (which will be referred to herein as an “LED chip”) is a semiconductor device that can radiate an emission in a bright color with high efficiency even though its size is small. The emission of an LED chip has an excellent monochromatic peak. To produce white light from LED chips, a conventional LED lamp arranges red, green and blue LED chips close to each other and gets the light rays in those three different colors diffused and mixed together. An LED lamp of this type, however, easily produces color unevenness because the LED chip of each color has an excellent monochromatic peak. That is to say, unless the light rays emitted from the respective LED chips are mixed together uniformly, color unevenness will be produced inevitably in the resultant white light. Thus, to overcome such a color unevenness problem, an LED lamp for producing white light by combining a blue LED chip and a yellow phosphor was developed (U.S. Pat. No. 5,998,925 and Japanese Patent No. 2998696, for example)

According to the technique disclosed in U.S. Pat. No. 5,998,925, white light is produced by combining together the emission of a blue LED chip and the yellow emission of a yellow phosphor, which is produced when excited by the emission of the blue LED chip. That is to say, the white light can be produced by using just one type of LED chips. That is why the color unevenness problem, which arises when white light is produced by arranging multiple types of LED chips close together, is avoidable.

The LED lamp with the bullet-shaped appearance as disclosed in Japanese Patent No. 2998696 has a configuration such as that illustrated in FIG. 1. As shown in FIG. 1, the bullet-shaped LED lamp 200 includes an LED chip 121, a bullet-shaped transparent housing 127 to cover the LED chip 121, and leads 122a and 122b to supply current to the LED chip 121. A cup reflector 123 for reflecting the emission of the LED chip 121 in the direction pointed by the arrow D is provided for the mount portion of the lead 122b on which the LED chip 121 is mounted. The LED chip 121 is encapsulated with a first resin portion 124, in which a phosphor 126 is dispersed and which is further encapsulated with a second resin portion 125. If the LED chip 121 emits a blue light ray, the phosphor 126 is excited by the blue light ray to produce a yellow light ray. As a result, the blue and yellow light rays are mixed together to produce white light.

However, the luminous flux of a single LED chip is too low. Accordingly, to achieve a luminous flux comparable to that of an incandescent lamp, a fluorescent lamp or any other general illumination used extensively today, an LED lamp preferably includes a plurality of LED chips that are arranged as an array on the same substrate. An LED lamp of that type is disclosed in U.S. Pat. No. 6,949,772, for example.

An LED lamp in which a plurality of LED bare chips are arranged on a heat-dissipating substrate is disclosed in U.S. Pat. No. 6,949,772. FIGS. 2A and 2B illustrate such an LED lamp.

As shown in FIG. 2A, a number of LED bare chips 202 are mounted on one surface of a heat-dissipating substrate 201. The heat-dissipating substrate 201, on which the LED bare chips 202 are mounted, is further combined with an optical reflector 203. The optical reflector 203 has the same number of openings (or holes) 203b as that of the LED bare chips 201 that are arranged on the heat-dissipating substrate 201. The inner wall of each of these openings 203b functions as a reflective surface 203a.

By combining the heat-dissipating substrate 201 on which the LED bare chips 202 have been mounted with the optical reflector 203, an LED lamp 250 such as that shown in FIG. 2B is obtained. In the LED lamp 250 shown in FIG. 2B, the openings 203b of the optical reflector 203 are filled with a resin 204, which functions as a lens.

In the LED lamp 250, a number of LED bare chips 202 are arranged highly densely on the heat-dissipating substrate 201, which nonetheless can efficiently dissipate the heat generated from those LED bare chips 202. As a result, the LED lamp 250 achieves a high luminous flux overall because a large amount of current can be supplied to each of those LED bare chips 202.

The optical reflector 203 may be made of either a metal such as aluminum or a resin. If the optical reflector 203 is made of a metal, the heat-dissipating effects can be enhanced by taking advantage of the high thermal conductivity of the metal. Besides, since the internal surface of the openings 203b of the optical reflector 203 may be a mirror surface, the internal surface of each opening that has been cut through a metal plate may be used as the reflective surface 203a as it is. However, if the optical reflector 203 is made of a metal, a high patterning cost needs to be paid to cut those openings 203b highly precisely, thus increasing the price of the optical reflector 203.

To mass-produce the LED lamps 250, the optical reflector 203 is preferably made of a resin rather than a metal, because a resin is much less expensive than a metal and also because optical reflectors made of a resin can be manufactured in great quantities using a mold.

If such a resin optical reflector 203 were used, however, the heat-dissipating substrate 201 might be warped. The openings 203b of the optical reflector 203 are usually filled with the resin 204 as described above, and the entire upper surface of the optical reflector 203 is sometimes coated with the resin 204. Just like the resin optical reflector 203, the resin 204 is formed by an injection molding process or any other molding process. That is why the resin 204 shrinks when cured. If the resin 204 shrank on the upper surface of the substrate, then the entire optical reflector 203 would shrink parallel to the upper surface of the heat-dissipating substrate 201, thus warping the heat-dissipating substrate 201 badly. Such a warp is even more significant when the heat-dissipating substrate 201 is thin.

For that reason, to prevent such a resin optical reflector 203 from being warped, the heat-dissipating substrate 201 needs to be thickened and its strength should be increased. Nevertheless, if the heat-dissipating substrate 201 were thickened, then it would be difficult to reduce the thickness of the LED lamp 250 that could be used as card LED lamp otherwise. As a result, the advantages of the thin, card LED lamp 250 would diminish. On top of that, such a thickened heat-dissipating substrate 201 would raise the material cost accordingly. Likewise, even if a special material were adopted for the reflector in order to increase the strength of the substrate while maintaining an appropriate thickness, the material cost would rise, too.

In order to overcome the problems described above, an object of the present invention is to provide an LED lamp, which can be manufactured at a relatively low cost and yet can minimize the warp effectively.

### SUMMARY OF THE INVENTION

An LED lamp according to the present invention includes: a substrate with an upper surface; a plurality of LED chips, which are arranged on the upper surface of the substrate; and a reflector, which has reflective surfaces that reflect emissions of the respective LED chips at least partially. The reflector includes a resin and a framework that is made of a material having a higher flexural rigidity than the resin.

In one preferred embodiment of the present invention, the framework is made of at least one of a metal, a ceramic, a semiconductor and glass.

In another preferred embodiment, the reflector has a plurality of openings that are arranged two-dimensionally, and the inner wall of each said opening surrounds side surfaces of an associated one of the LED chips.

In this particular preferred embodiment, the respective inner walls of the openings of the reflector function as the reflective surfaces.

In still another preferred embodiment, the LED lamp further includes a translucent member that covers the LED chips over the upper surface of the substrate.

In that case, the translucent member is made of a resin, and no resin layer is provided on the lower surface of the substrate.

In a specific preferred embodiment, the translucent member includes portions functioning as an array of lenses, and each of the lenses included in the array causes a lens effect on the emission that has been radiated from an associated one of the LED chips.

Alternatively or additionally, the translucent member covers at least the reflective surfaces of the reflector.

In yet another preferred embodiment, the LED lamp further includes wavelength converting portions, each of which covers an associated one of the LED chips and converts the emission that has been radiated from the associated LED chip into light that has a longer wavelength than the emission.

In yet another preferred embodiment, the resin of the reflector covers at least 70% of the surface of the framework.

In yet another preferred embodiment, the substrate is a composite substrate made of a resin and a material including an inorganic filler.

In yet another preferred embodiment, the framework is located outside of a cluster that is formed by the LED chips on the upper surface of the substrate.

In yet another preferred embodiment, the LED chips are arranged in columns and rows on the upper surface of the substrate so as to form a matrix thereon, and the framework has at least two bars extending in a column direction and/or a row direction of the matrix.

In an alternative preferred embodiment, the framework includes members that extend in the column direction between the columns of the matrix and in the row direction between the rows thereof.

In yet another preferred embodiment, the LED chips are arranged in columns and rows on the substrate so as to form a matrix thereon, and the framework has at least two bars that extend obliquely across the columns and/or the rows of the matrix.

In yet another preferred embodiment, the framework is a plate member that is arranged parallel to the substrate, and openings are cut through the plate member so as to encircle their associated LED chips.

In yet another preferred embodiment, the framework is a metallic member with the reflective surfaces, and the resin of the reflector is deposited as a layer on the metallic member.

A reflector according to the present invention is designed for an LED lamp and includes a resin and a framework that is made of a material having a higher flexural rigidity than the resin.

In one preferred embodiment of the present invention, the framework is made of at least one of a metal, a ceramic, a semiconductor and glass.

In another preferred embodiment, the reflector has a plurality of openings that are arranged two-dimensionally, and the respective inner walls of the openings function as reflective surfaces for reflecting emissions that have been radiated from LED chips.

In still another preferred embodiment, the inner walls of the openings are defined by the surface of the resin at least partially.

In yet another preferred embodiment, the lower surface of the reflector is defined by the surface of the resin at least partially.

In an LED lamp according to the present invention, the reflector has a framework that is made of a material having a higher flexural rigidity than a resin. Thus, compared to a conventional reflector that is made of a resin only, the reflector of the present invention has significantly increased rigidity. As a result, LED lamps can be manufactured at a reduced cost with their warp minimized.

### BRIEF DESCRIPTION OF THE DRAWINGS

FIG. 1 is a cross-sectional view schematically illustrating a configuration for a conventional LED lamp with a bullet appearance.

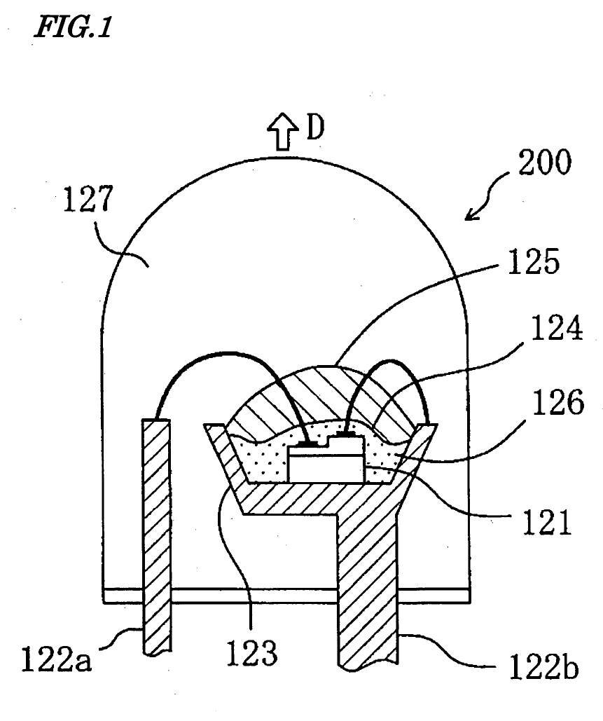

FIGS. 2A and 2B are perspective views schematically illustrating a configuration for another conventional LED lamp.

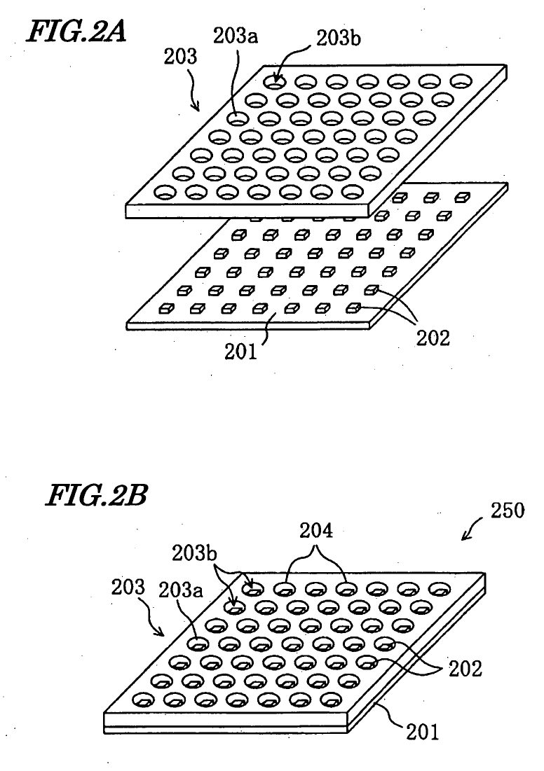

FIG. 3 is a cross-sectional view schematically illustrating a configuration for an LED lamp 100 according to a preferred embodiment of the present invention.

FIG. 4 is a plan view of the LED lamp 100 shown in FIG. 3.

FIG. 5 is a cross-sectional view schematically illustrating a configuration for an LED lamp 100 according to another preferred embodiment of the present invention.

FIG. 6 is a plan view of the LED lamp 100 shown in FIG. 3.

FIG. 7 is an enlarged cross-sectional view schematically illustrating the arrangement of an LED element 10 and its surrounding members.

FIG. 8 is a perspective view schematically illustrating a configuration for a card LED lamp 100 according to another preferred embodiment of the present invention.

FIG. 9 is a plan view illustrating an exemplary framework 40.

FIG. 10 is a plan view illustrating another exemplary framework 40.

FIG. 11 is a plan view illustrating still another exemplary framework 40.

FIG. 12 is a perspective view illustrating yet another exemplary framework 40.

FIG. 13 is a perspective view illustrating yet another exemplary framework 40.

FIG. 14 is a perspective view illustrating yet another exemplary framework 40.

### DETAILED DESCRIPTION OF PREFERRED EMBODIMENTS

Hereinafter, preferred embodiments of an LED lamp according to the present invention will be described with reference to the accompanying drawings, in which any pair of components having substantially the same function and illustrated in multiple drawings will be identified by the same reference numeral for the sake of simplicity.

### Embodiment 1

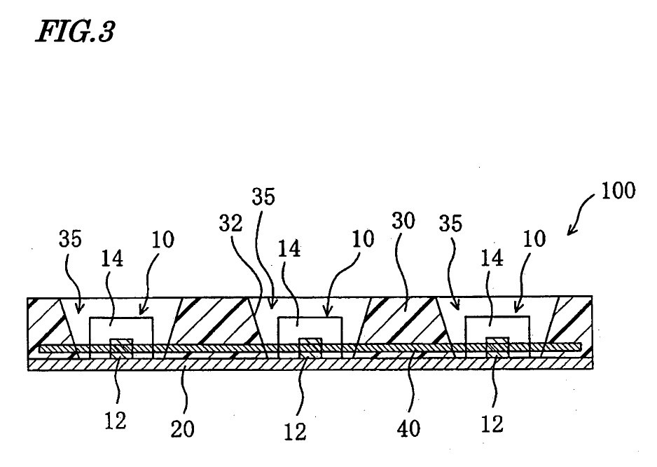

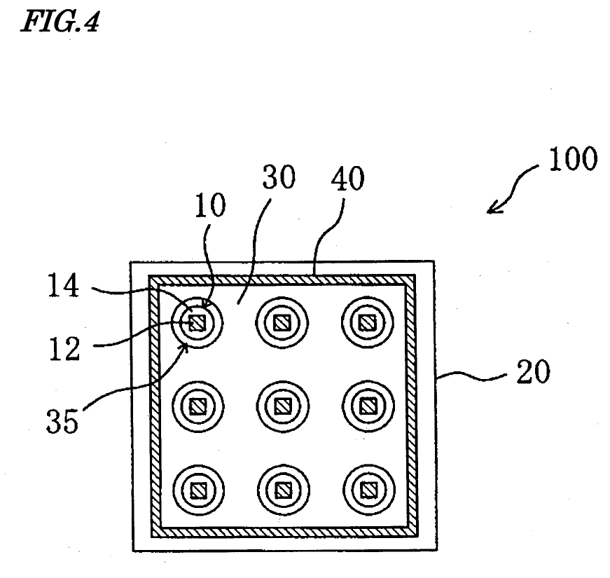

First, an LED lamp according to a first preferred embodiment of the present invention will be described with reference to FIGS. 3 and 4. A cross-sectional structure of the LED lamp 100 is schematically illustrated in FIG. 3 and a planar layout thereof is schematically illustrated in FIG. 4.

The LED lamp 100 includes a substrate 20, LED elements 10 that are arranged two-dimensionally on the substrate 20, and a reflector 30 with reflective surfaces 32 for reflecting the emissions of the LED elements 10.

The reflector 30 may be implemented as a plate resin layer including a framework 40 inside. This resin layer has a plurality of openings, each of which is arranged so as to surround the side surfaces of its associated LED element 10. The framework 40 is made of a material that has a higher flexural rigidity than that of the resin layer of the reflector 30, thereby minimizing the warp of the substrate 20. The framework 40 is preferably made of at least one of a metal, a ceramic, a semiconductor and glass.

The resin of the reflector 30 may be a liquid crystal polymer (LCP) or polyphthalamide (PPA), for example. Each of these resin materials has a relatively high flexural rigidity, which is typically 120 MPa or more. Specifically, the liquid crystal polymer has a flexural rigidity of about 150 MPa to about 250 MPa and polyphthalamide has a flexural rigidity of about 120 MPa to about 370 MPa.

On the other hand, a metal (e.g., aluminum) that can be used effectively as a material for the framework 40 has a flexural rigidity of about 400 MPa to about 500 MPa. A ceramic has a flexural rigidity of about 800 MPa to about 1,100 MPa.

In the example illustrated in FIGS. 3 and 4, the framework 40 of the reflector 30 is made of aluminum. Alternatively, the framework 40 may also be made of copper, stainless steel, iron, or an alloy thereof. If the framework 40 is made of a ceramic, alumina (Al₂O₃), mullite (3Al₂O₃·2SiO₂), steatite (MgO·2SiO₂), forsterite (2MgO·2SiO₂) or zirconia (PSZ) may be used as the ceramic material.

In this preferred embodiment, an LED cluster is formed by nine LED elements 10 that are arranged in a 3×3 matrix (i.e., in three columns and in three rows), and the reflector 30 with nine openings 35, each of which surrounds an associated one of the LED elements 10, covers the upper surface of the substrate 20 as shown in FIG. 4.

As also shown in FIG. 4, the framework 40 is arranged so as to surround the outer edges of the LED cluster. More specifically, the framework 40 has a rectangular shape, is embedded in the resin layer and is located along the outer edges of the substrate 20. The resin layer may have a thickness of 500 μm to 10 mm, for example. The thickness of the framework 40 is smaller than that of the resin layer and may be 100 μm to 5 mm. In the example illustrated in FIGS. 3 and 4, the resin layer has a thickness of 1 mm and the framework 40 has a thickness of about 200 μm. The framework 40 is located about 200 μm to about 300 μm over the bottom of the resin layer. In other words, a gap of about 200 μm to about 300 μm is provided between the framework 40 and the substrate 20 and is filled with a portion of the resin layer.

The side surface (i.e., the inner wall) of each of the openings 35 of the resin layer functions as a reflective surface 32 for reflecting the emission of its associated LED element 10. The reflective surfaces 32 preferably have a reflectance of 70% or more. And the reflective surfaces 32 may be either surfaces of a resin or those of a metal film (i.e., reflective film) that has been deposited on the reflector 30. If such a reflective film is made of Ni, Al, Pt, Ag or Au, the reflectance of the reflective surfaces 32 can be increased. When made of a titanium oxide film, for example, the reflective surfaces 32 may be white.

The diameter of those openings 35 is changeable with the sizes of the LED elements 10 but may be about 2,100 μm to about 2,500 μm in this preferred embodiment.

The LED element 10 of this preferred embodiment includes an LED bare chip 12 and a phosphor resin portion 14 that covers the LED bare chip 12. The phosphor resin portion 104 includes a phosphor (luminophor) for converting the emission of the LED bare chip 12 into light having a longer wavelength than that of the emission and a resin in which the phosphor is dispersed. The LED bare chip 12 is mounted on the upper surface of the substrate 20. A interconnect pattern (not shown) is also arranged on the upper surface of the substrate 20. And the LED bare chip 12 may be flip-chip bonded to a portion (e.g., a land) of the interconnect pattern according to this preferred embodiment.

The LED bare chip 12 for use in this preferred embodiment is an LED chip that produces light having a peak wavelength falling within the visible range of 380 nm to 780 nm. The phosphor dispersed in the phosphor resin portion 14 produces an emission that has a different peak wavelength from that of the LED bare chip 12 within the visible range of 380 nm to 780 nm. The LED bare chip 12 is preferably a blue LED that emits a blue light ray. In that case, the phosphor included in the phosphor resin portion 14 is a yellow phosphor that transforms the blue ray into a yellow ray. The blue and yellow rays mix each other to produce white light. In order to produce white light with little unevenness by mixing these rays together sufficiently, the reflective surface 32 may be a diffusing surface. For that purpose, titanium oxide may be added into the resin.

The LED bare chip 12 is preferably an LED chip made of a gallium nitride (GaN) based material and emits light with a wavelength of 460 nm, for example. For example, if a blue-ray-emitting LED chip is used as the LED bare chip 12, then (Y·Sm)₃, (Al·Ga)₅O₁₂:Ce or (Y_{0.39}Gd_{0.57}Ce_{0.03}Sm_{0.01})₃Al₅O₁₂ may be used effectively as the phosphor. In this preferred embodiment, the phosphor resin portion 14 preferably has a substantially cylindrical shape. If the LED bare chip 12 has approximately 0.3 mm×0.3 mm dimensions, then the phosphor resin portion 14 may have a diameter of about 0.7 mm to about 0.9 mm, for example. Alternatively, the phosphor resin portion 14 may have a rectangular cross section horizontally, not such a circular cross section.

In the example illustrated in FIG. 4, nine LED elements 10 are arranged as a 3×3 matrix on the upper surface of the substrate 20. However, the number and arrangement of the LED elements 10 are not limited to those adopted in this example. Speaking more generally, LED elements 10 may be arranged on a single substrate 20 so as to form a matrix of M rows and N columns, where M and N are both integers that are equal to or greater than two. Furthermore, the LED elements 10 do not have to be arranged in such a matrix pattern but may even be arranged almost concentrically or spirally, too.

The substrate 20 is preferably a heat-dissipating substrate. In this preferred embodiment, the substrate 20 is a composite substrate made of a resin and a material including an inorganic filler. More specifically, a metal-based composite substrate (e.g., an alumina composite substrate) may be used. By using a composite substrate as the substrate 20, a heat-dissipating substrate with a high thermal conductivity (of 1.2° C./W or more, for example) is realized, a large amount of current can be supplied to each LED bare chip, and eventually a high luminous flux is achieved.

The substrate 20 preferably has a thickness of 0.1 mm to 5 mm and typically has a thickness of 2 mm or less. For example, if the substrate 20 is implemented as a thin composite substrate (with a thickness of 1 mm, for example), then the substrate 20 is very likely to be warped due to the effect of the resin reflector 30. In the arrangement of this preferred embodiment, however, the reflector 30 is reinforced with the framework 40, and therefore, the warp can be reduced and minimized. To mount a number of LED elements 10 thereon, the substrate 20 preferably has an upper surface area of at least 6.25 mm². More preferably, the substrate 20 has an upper surface area of 56.25 mm² or more to achieve a high luminous flux by mounting a lot of LED elements 10 thereon.

In this preferred embodiment, the metallic framework 40 is entirely covered with the resin of the reflector 30. By covering most of the framework 40 with the resin, the metallic framework 40 can be electrically insulated from the interconnects and other components on the substrate 20 and the oxidation of the framework 40 can be minimized, too. No serious problem will arise even if the framework 40 is partially exposed out of the resin. Even so, at least 70% of the surface of the framework 40 is preferably coated with the resin.

In the example illustrated in FIG. 3, the framework 40 is located in the lower half of the resin layer of the reflector 30. Alternatively, the framework 40 may be located either in the upper half, or at the center, of the resin layer of the reflector 30. Optionally, the framework 40 may be located at the bottom of the resin layer and in contact with the substrate 20. In that case, however, if the framework 40 is made of a material with electrical conductivity, the surface of the interconnect pattern on the substrate 20 needs to be coated with an insulator (such as a resin) at least partially to keep the framework 40 electrically insulated from the interconnect pattern.

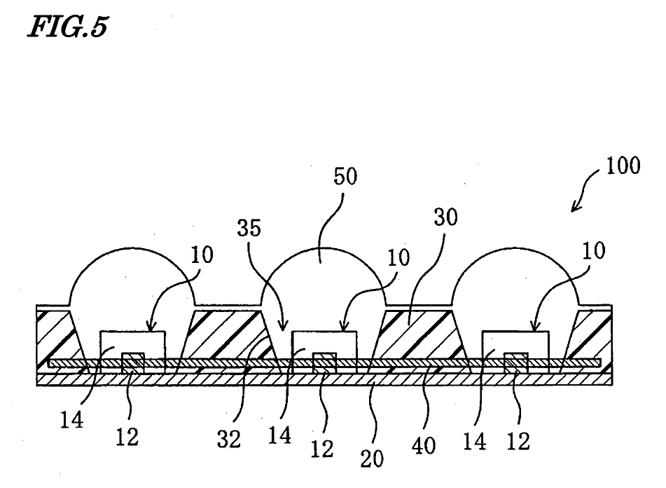

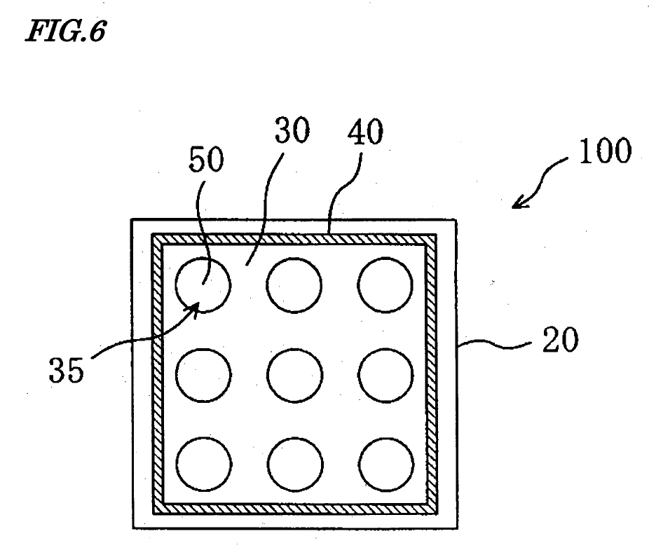

The openings 35 of the reflector 30 shown in FIG. 3 may be filled with a translucent member made of a resin, for example. As shown in FIGS. 5 and 6, the respective openings 35 may be filled with resin lenses 50, for instance. FIG. 5 is a cross-sectional view similar to FIG. 3. And FIG. 6 is a plan view showing the framework 40, which is actually embedded in the reflector 30, to make the arrangement of this preferred embodiment easily understandable.

In the LED lamp 100 shown in FIGS. 5 and 6, the spatial distribution of the light emitted from the LED elements 10 can be controlled with the array of the resin lenses 50, and the optical characteristics of the LED lamp 100 can be improved as a result. According to the arrangement of this preferred embodiment, the framework 40 is provided in the reflector 30. That is why even if the reflector 30 is going to be warped to a greater degree due to the shrinkage of the resin lenses 50, such a warp can also be minimized. In general, if such resin lenses 50 are provided on the upper surface of the substrate 20 while no resin layer is provided on the lower surface of the substrate 20, then the substrate 20 will be warped particularly significantly due to the shrinkage of the resin on one side of the substrate. To minimize such a warp, a resin layer may be provided intentionally on the lower surface of the substrate 20. According to this preferred embodiment, however, the lower surface of the substrate 20 is not covered with any resin layer to improve the heat dissipation ability of the substrate 20. As a result, the resin shrinks only on the upper surface of the substrate 20. But the warp of the substrate 20 can be reduced significantly with the presence of the framework 40 in the reflector 30.

The lenses 50 can be made by filling the openings 35 with a resin to encapsulate the respective LED elements 10 and molding the resin into a predetermined shape. In the example illustrated in FIG. 5, a thin resin layer extending laterally from the lenses 50 also covers the upper surface of the reflector 30. By adopting such an arrangement, the array of lenses 50 can be made at the same time more easily. The lenses 50 may be made of epoxy resin, for example. However, the lenses 50 do not have to be made of a resin but may be made of glass instead.

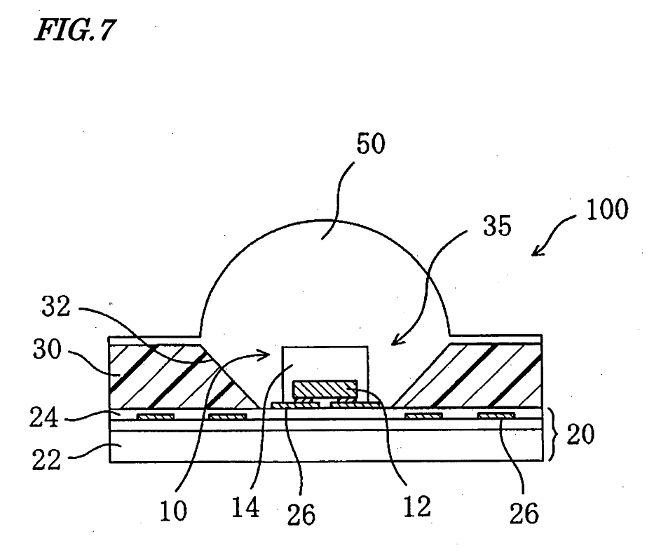

FIG. 7 is a cross-sectional view illustrating a single LED element 10 and its surrounding members in the LED lamp 100. In the example illustrated in FIG. 7, the substrate 20 includes a base substrate 22 and an interconnect layer 24, which has been formed on the base substrate 22. The base substrate 22 may be a metallic substrate, for example. And the interconnect layer 24 includes an interconnect pattern 26 that has been formed on a composite layer consisting of an inorganic filler and a resin. It is to dissipate the heat generated from the LED bare chips 12 more efficiently that a metallic substrate and a composite layer are used as the base substrate 22 and as the interconnect layer 24, respectively. In this example, the interconnect layer 24 is a part of a multilayer interconnect substrate, and the LED bare chips 12 are flip-chip bonded to the interconnect pattern 26 on the uppermost layer. In this preferred embodiment, the reflector 30 is made of a resin, and therefore, the interconnect pattern 26 can be kept electrically insulated better compared to a situation where a metallic reflector is used.

Also, in the arrangement illustrated in FIG. 7, the side surface of the phosphor resin portion 14 is spaced apart from the reflective surface 32 of the reflector 30. By providing such a gap between the side surface of the phosphor resin portion 14 and the reflective surface 32, the shape of the phosphor resin portion 14 can be determined more freely without being restricted by that of the reflective surface 32 of the reflector 30. The shape of the phosphor resin portion 14 determines the degree of color unevenness. That is why by optimizing the shape of the phosphor resin portion 14 independently of that of the reflective surface 32, the color unevenness can be reduced.

A similar LED lamp in which a gap is also provided between the side surface of the phosphor resin portion 14 and the reflective surface 32 of the reflector 30 is disclosed in U.S. Pat. No. 6,963,166, the entire disclosure of which is hereby incorporated by reference.

As shown in FIG. 4, the phosphor resin portions 14 of this preferred embodiment have a “substantially cylindrical shape”. As used herein, the “substantially cylindrical shape” refers to not only a structure having a completely round cross section parallel to the upper surface of the substrate but also a structure having a polygonal cross section with at least six vertices. This is because a polygon with six or more vertices is substantially axisymmetric and may be regarded as almost identical with a “circle”.

If the LED bare chip 12 is ultrasonic flip-chip bonded onto the substrate 20, then the LED bare chip 12 will sometimes turn slightly due to ultrasonic vibrations on a plane parallel to the upper surface of the substrate. In such a situation, if the phosphor resin portion 14 had a triangular or quadrangular prism shape, then the spatial distribution of the light would easily change according to the positional relationship between the LED bare chip 12 and the phosphor resin portion 14. However, even if a substantially cylindrical phosphor resin portion 14 has turned on a plane that is parallel to the upper surface of the substrate, the relative positional relationship between the phosphor resin portion 14 and the LED bare chip 12 will not change significantly and the spatial distribution of light will be hardly affected.

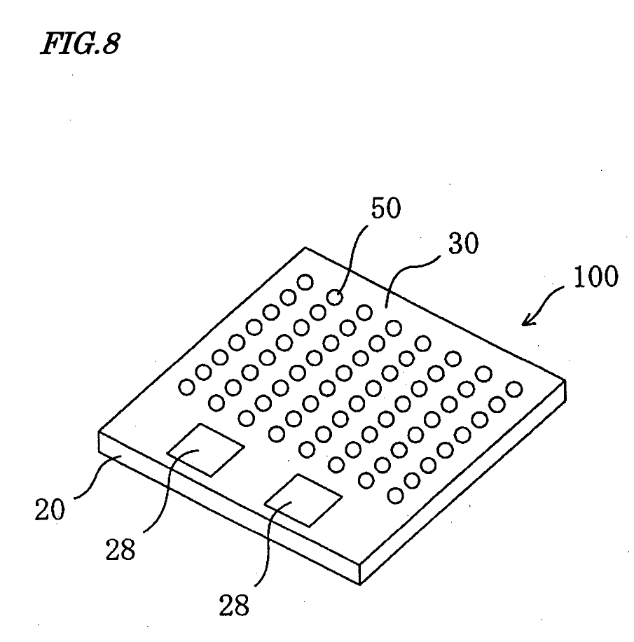

FIG. 8 illustrates an exemplary card LED lamp 100 including a two-dimensional arrangement of LED elements (i.e., a group or a cluster of LED elements). In the card LED lamp 100 shown in FIG. 8, a number of lenses 50 are arranged on the surface and a framework (not shown) is embedded in the reflector 30 made of a resin. That framework may have the same shape as the framework 40 shown in FIG. 6.

On the surface of the card LED lamp 100, provided are feeder terminals 28, which are electrically connected to the interconnect pattern on the substrate 20 in order to supply power to the LED bare chips. To use this card LED lamp 100, a connector (not shown), to/from which the LED lamp 100 is readily insertable and removable, may be electrically connected to a lighting circuit (not shown) and then the card LED lamp 100 may be inserted into that connector.

Although it depends on the standard or specification to comply with, the card LED lamp 100 often needs to have a reduced thickness. Normally, if one attempted to reduce the thickness of a card LED lamp including the reflector 30 made of a resin (and the resin lenses 50), then the warp problem would get serious more often than not. According to the arrangement of this preferred embodiment, however, the resin reflector 30 is reinforced with the framework 40, and therefore, even the card LED lamp would not be warped.

In the preferred embodiment described above, the framework 40 is arranged in the peripheral area of the substrate 20. However, the framework 40 is never limited to such a pattern but may have any other pattern.

### Embodiment 2

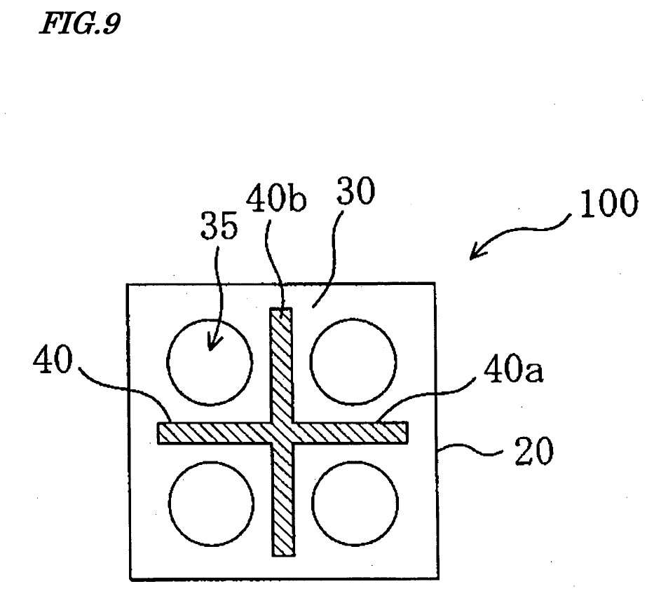

Next, a second preferred embodiment of an LED lamp according to the present invention will be described with reference to FIG. 9.

FIG. 9 illustrates an LED lamp including a framework 40 in the shape of a cross. The framework 40 shown in FIG. 9 includes a first bar member 40a extending in the row direction parallel to the upper surface of the substrate 20 and a second bar member 40b extending in the column direction parallel to the upper surface of the substrate 20. The first and second bar members 40a and 40b may either form two integral parts of the single framework 40 or be a combination of two separate members. Optionally, the height (or the level) of the first bar member 40a as measured from the upper surface of the substrate 20 may be different from that of the second bar member 40b as measured from the same surface of the substrate 20 and the first and second bar members 40a and 40b may cross each other. In that case, the two bar members 40a and 40b that cross each other are preferably coupled together. Such coupling may be done either by a projection extending from at least one of the bar members 40a and 40b or any other fixing member. Also, if the two bar members 40a and 40b are arranged to cross each other at almost the same height, then at least one of the two bar members 40a and 40b may have either a notch or a through hole to receive and pass the other member.

### Embodiment 3

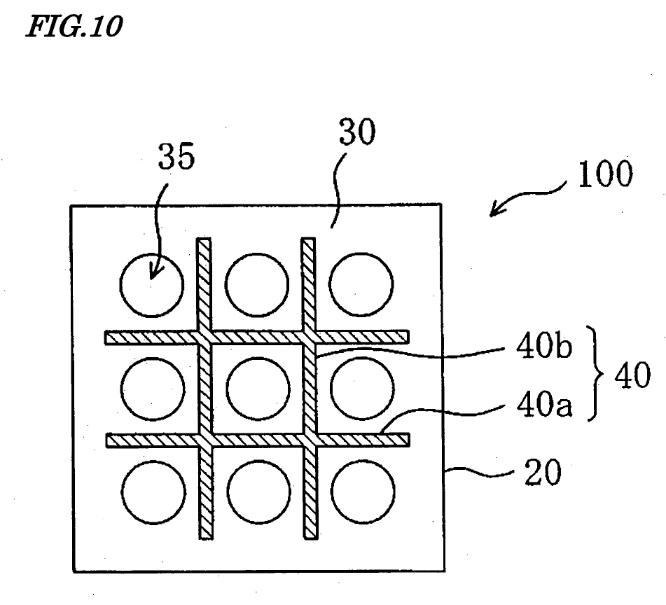

Next, a third preferred embodiment of an LED lamp according to the present invention will be described with reference to FIG. 10.

The framework 40 shown in FIG. 10 has a lattice shape, which is formed by a first set of bar members 40a and a second set of bar members 40b. In the example illustrated in FIG. 10, two bar members 40a of the first set cross two bar members 40b of the second set. However, depending on the arrangement of LED elements 10, an arrangement in which a greater number of bar members 40a and 40b cross each other may also be adopted.

### Embodiment 4

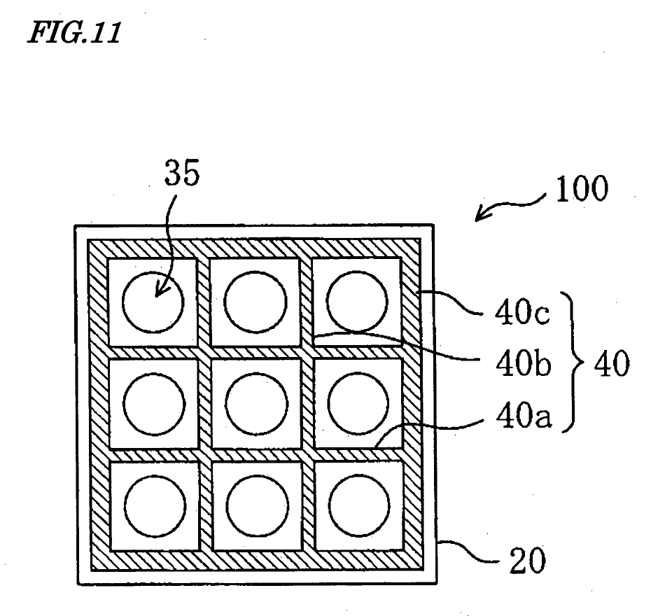

Next, a fourth preferred embodiment of an LED lamp according to the present invention will be described with reference to FIG. 11.

The framework 40 shown in FIG. 11 is a combination of the two frameworks 40 shown in FIGS. 6 and 10, respectively. That is to say, the framework 40 shown in FIG. 11 consists of members 40a and 40b forming a lattice shape and another member 40c that surrounds the outer edges of the LED cluster.

According to this preferred embodiment, the warp can be reduced in the peripheral area that is usually most likely to be warped.

### Embodiment 5

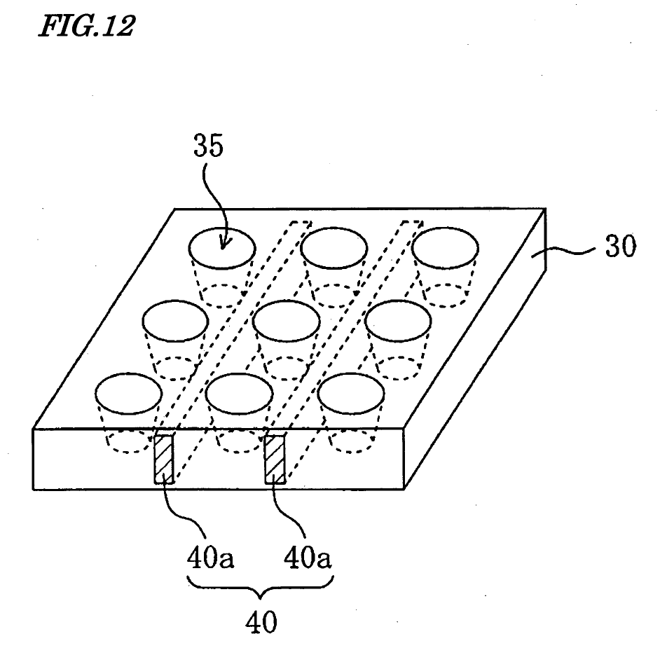

Next, a fifth preferred embodiment of an LED lamp according to the present invention will be described with reference to FIG. 12.

The framework 40 shown in FIG. 12 includes at least two bar members 40a that extend either in the row direction or in the column direction. The two bar members 40a extend substantially parallel to each other without crossing each other. The warp can also be minimized by using such a framework 40.

If only one bar member 40a were provided, the warp usually could not be reduced sufficiently in a direction (e.g., in the column direction) that is different from the length direction (e.g., the row direction) of the bar member 40a. However, if the reflector 30 has a planar shape that is elongated in one direction, then even just one bar member 40a can minimize the warp effectively by aligning the length direction of the bar member 40a with that of the reflector 30.

### Embodiment 6

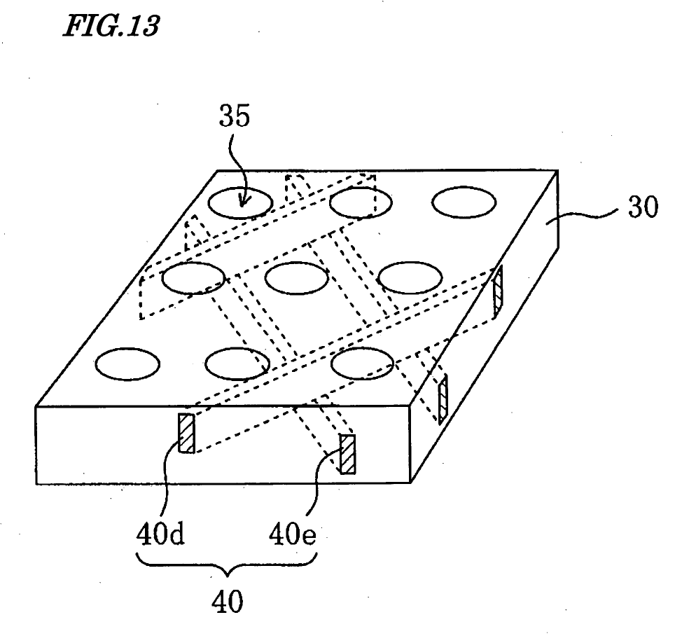

Next, a sixth preferred embodiment of an LED lamp according to the present invention will be described with reference to FIG. 13.

As shown in FIG. 13, the framework 40 may also be formed by arranging bar members 40d and 40e obliquely to the four sides of the substrate or to the column or row direction of the matrix of the LED cluster. The bar members 40d and 40e may either form integral parts of the single framework 40 or be a combination of separate members.

As used herein, the “bar member” includes a wire. Accordingly, a mesh formed by weaving metal wires may also be used as the framework 40.

### Embodiment 7

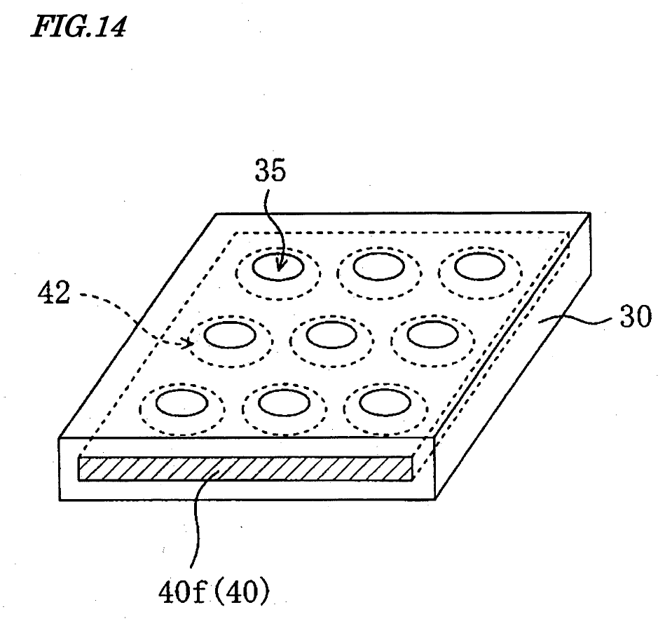

Next, a seventh preferred embodiment of an LED lamp according to the present invention will be described with reference to FIG. 14.

The framework 40 shown in FIG. 14 is a plate member 40f having openings 42, which are arranged so as to encircle the respective LED elements 10. The openings 35 of the reflector 30 are arranged so as to extend through their associated openings 42.

The framework 40 shown in FIG. 14 can be made by subjecting the plate member 40f to a pressing process and therefore, is mass-producible easily. Also, the plate member 40f has a shape with such a high bending stress as to minimize the warp effectively. The reflective surfaces 32 of the reflector 30 may be made of a resin or the side surfaces (i.e., the inner walls) of the openings 42 of the plate member 40f.

In the preferred embodiments illustrated in FIGS. 12, 13 and 14, the framework 40 is fully covered with the resin of the reflector 30. Alternatively, the framework 40 may be partially exposed out of the resin of the reflector 30. Even so, the warp could be minimized equally effectively. It should be noted that if the reflector 30 is made by a resin molding process, it is rather difficult to embed the framework 40 in the resin entirely. To embed the framework 40 in the resin fully, the framework 40 should be spaced apart from the inner wall of the molding die. Actually, however, the framework 40 needs to be supported in a floating position to do so. More specifically, projections or bent portions should be provided for parts (e.g., both ends) of the framework 40 and the resin should be cured with the framework 40 supported on the projections, for example. In that case, portions of the framework 40 (such as the projections) may be exposed on the surface of the resin.

Optionally, a conventional metallic reflector may be used as the framework 40. In that case, a resin layer needs to be deposited on the metallic reflector functioning as the framework 40. Specifically, first, a metallic reflector to be the framework 40 is prepared, and then a resin layer is deposited on the metallic reflector, thereby making the reflector 30. The resin layer is preferably made by a resin molding process that uses a die. The molded resin layer should have openings that extend through their associated openings of the metallic reflector. The reflective surfaces 32 of the reflector 30 are defined by the inner walls of those openings of the resin layer.

Compared to a conventional metallic reflector, the metallic reflector for use in any of the preferred embodiments described above may have openings that have been patterned less accurately and can be made at a reduced cost. If the conventional metallic reflector were used as a reflector as it is, then the inner walls of the openings of that metallic reflector should function as reflective surfaces. That is why those walls should be patterned highly accurately, which means it would take a lot of trouble and a significantly increased patterning cost.

In addition, in the reflector 30 made by the method described above, the metallic reflector, functioning as the framework, has its surfaces covered with the resin, and therefore, the interconnect pattern on the substrate 20 can be electrically insulated easily.

A white LED lamp 100 according to any of the preferred embodiments of the present invention described above includes an LED element 10 consisting of a blue LED bare chip 12 and a yellow phosphor 14. However, the white LED lamp may include any other type of LED elements. For example, a white LED lamp may include LED elements, each comprised of an ultraviolet LED bare chip for producing an ultraviolet emission and a phosphor that is excited with the emission of the ultraviolet LED bare chip to produce red (R), green (G) and blue (B) rays. In a preferred embodiment, the ultraviolet LED bare chip produces an emission with a wavelength of 380 nm to 400 nm and the phosphor producing the red (R), green (G) and blue (B) rays has three peak wavelengths within the visible range of 380 nm to 780 nm (i.e., at wavelengths of 450 nm, 540 nm and 610 nm, respectively).

In the preferred embodiments described above, each white LED element 10 includes an LED bare chip 12. Alternatively, an LED according to another preferred embodiment of the present invention may be an LED with a bullet appearance (such as a surface mounted LED).

In the preferred embodiments described above, one phosphor resin portion 14 covers one LED bare chip 12. However, a single phosphor resin portion 14 may cover two or more LED bare chips 12. For example, one phosphor resin portion 14 may cover a first LED bare chip 12 and a second LED bare chip 12. In that case, the first and second LED bare chips 12 may emit either light rays falling within the same wavelength range or light rays falling within mutually different wavelength ranges. For example, the first LED bare chip 12 may be a blue LED chip and the second LED bare chip 12 may be a red LED chip. When the blue LED chip 12 and red LED chip 12 are both used, a white LED lamp, of which the color rendering performance is excellent in the color red, can be obtained.

More specifically, if a blue LED bare chip and a yellow phosphor are combined, white light can be produced but that white light is somewhat short of red components. Consequently, the resultant white LED lamp exhibits insufficient color rendering performance in the color red. However, if the red LED bare chip 12 is combined with the blue LED bare chip 12, then the color rendering performance of the white LED lamp in the color red can be improved. As a result, an LED lamp that can be used even more effectively as general illumination is realized.

The LED element 10 does not have to be a white LED element. Alternatively, the LED element 10 may also an LED element emitting a light ray in a single color such as a red LED element, a green LED element or a blue LED element. This is because according to the present invention, the warp due to the shrinkage of the resin can be minimized with the framework of the reflector, no matter what color the emission of the LED element has.

An LED lamp according to the present invention is thin but is not warped easily and can be manufactured at a significantly reduced cost. Thus, the LED lamp can be used effectively as any of various types of illumination sources.

While the present invention has been described with respect to preferred embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

What is claimed is:

1. An LED lamp comprising:
a substrate with an upper surface and a lower surface;
a plurality of LED chips, which are arranged on the upper surface of the substrate; and
a reflector, which has reflective surfaces that reflect emissions of the respective LED chips at least partially,
wherein the reflector includes a resin and a framework having a higher flexural rigidity than the resin.

2. The LED lamp of claim 1, wherein the framework is made of at least one of a metal, a ceramic, a semiconductor and glass.

3. The LED lamp of claim 1, wherein the reflector has a plurality of openings that are arranged two-dimensionally, and
wherein the inner wall of each said opening surrounds side surfaces of an associated one of the LED chips.

4. The LED lamp of claim 3, wherein the respective inner walls of the openings of the reflector function as the reflective surfaces.

5. The LED lamp of claim 1, further comprising a translucent member that covers the LED chips over the upper surface of the substrate.

6. The LED lamp of claim 5, wherein the translucent member is made of a resin, and
wherein no resin layer is provided on the lower surface of the substrate.

7. The LED lamp of claim 6, wherein the translucent member includes portions functioning as an array of lenses, and
wherein each of the lenses included in the array causes a lens effect on the emission that has been radiated from an associated one of the LED chips.

8. The LED lamp of claim 6, wherein the translucent member covers at least the reflective surfaces of the reflector.

9. The LED lamp of claim 1, further comprising wavelength converting portions, each of which covers an associated one of the LED chips and converts the emission that has been radiated from the associated LED chip into light that has a longer wavelength than the emission.

10. The LED lamp of claim 1, wherein the resin of the reflector covers at least 70% of the surface of the framework.

11. The LED lamp of claim 1, wherein the substrate is a composite substrate made of a resin and a material including an inorganic filler.

12. The LED lamp of claim 1, wherein the framework is located outside of a cluster that is formed by the LED chips on the upper surface of the substrate.

13. The LED lamp of claim 1, wherein the LED chips are arranged in columns and rows on the upper surface of the substrate so as to form a matrix thereon, and
wherein the framework has at least two bars extending in a column direction and/or a row direction of the matrix.

14. The LED lamp of claim 12, wherein the framework includes members that extend in the column direction between the columns of the matrix and in the row direction between the rows thereof.

15. The LED lamp of claim 1, wherein the LED chips are arranged in columns and rows on the substrate so as to form a matrix thereon, and
wherein the framework has at least two bars that extend obliquely across the columns and/or the rows of the matrix.

16. The LED lamp of claim 1, wherein the framework is a plate member that is arranged parallel to the substrate, and
wherein openings are cut through the plate member so as to encircle their associated LED chips.

17. The LED lamp of claim 1, wherein the framework is a metallic plate member having openings, and
wherein the resin of the reflector is formed as a layer on the metallic plate member.

18. The LED lamp of claim 1, wherein the LED lamp is a card LED lamp.

19. A reflector for use in an LED lamp, the reflector comprising a resin and a framework having a higher flexural rigidity than the resin,
wherein the reflector has a plurality of openings that are arranged two-dimensionally, and
wherein the respective inner walls of the openings function as reflective surfaces for reflecting emissions that have been radiated from LED chips.

20. The reflector of claim 19, wherein the framework is made of at least one of a metal, a ceramic, a semiconductor and glass.

21. The reflector of claim 19, wherein the inner walls of the openings are defined by the surface of the resin at least partially.

22. The reflector of claim 19, wherein the lower surface of the reflector is defined by the surface of the resin at least partially.

23. The LED lamp of claim 1, wherein the framework is made of a material having a higher flexural rigidity than the resin.
